(19) United States
(12) Patent Application Publication
(10) Pub. No.: US 2020/0087783 A1
(43) Pub. Date: Mar. 19, 2020

(54) PATTERNING METAL REGIONS ON METAL OXIDE FILMS/METAL FILMS BY SELECTIVE REDUCTION/OXIDATION USING LOCALIZED THERMAL HEATING

(71) Applicant: Board of Regents, The University of Texas System, Austin, TX (US)

(72) Inventors: Roger BONNECAZE, Austin, TX (US); Meghali CHOPRA, Austin, TX (US); Sonali CHOPRA, Austin, TX (US); Jeremy BINAGIA, Austin, TX (US); John EKERDT, Austin, TX (US); Bryce EDMONDSON, Austin, TX (US)

(21) Appl. No.: 16/467,927

(22) PCT Filed: Dec. 6, 2017
(86) PCT No.: PCT/US2017/064952

§ 371 Date: Jun. 7, 2019

Related U.S. Application Data
(60) Provisional application No. 62/432,500, filed on Dec. 9, 2016.

(51) Int. Cl. C23C 16/40; C23C 16/455; C23C 16/56; C23C 14/00; C23C 14/08; C23C 14/58

(52) U.S. Cl. CPC C23C 16/406; C23C 16/45525; C23C 16/56; C23C 14/5853; C23C 14/085; C23C 14/5813; C23C 14/0036

(57) ABSTRACT

A method for creating metal patterns. A metal oxide film/metal film is deposited on a substrate in a reactor. After the metal oxide film/metal film has been deposited, the desired metal regions/metal oxide regions are formed on the metal oxide film/metal film using a reduction/oxidation reaction. A reducing/oxidizing gas is fed into the reactor. Furthermore, a heat source, such as a thermal probe or a high intensity laser beam, is pulsed to heat and form metal regions/metal oxide regions on the metal oxide film/metal film within the metal's reduction/oxidation window. In this manner, benefits over prior patterning techniques are achieved, including greater control and uniformity, reduced cost, less waste and potential for sub-5 nm features.

### CROSS REFERENCE TO RELATED APPLICATIONS

This application claims priority to U.S. Provisional Patent Application Ser. No. 62/432,500, entitled “Patterning Metal Regions on Metal Oxide Films/Metal Films by Selective Reduction/Oxidation Using Localized Thermal Heating,” filed on Dec. 9, 2016, which is incorporated by reference herein in its entirety.

### GOVERNMENT INTERESTS

This invention was made with government support under Grant No. EEC1160494 awarded by the National Science Foundation. The U.S. government has certain rights in the invention.

### TECHNICAL FIELD

The present invention relates generally to the creation of metal and metal oxide patterns, and more particularly to patterning metal regions on metal oxide films/metal films by selective reduction/oxidation using localized thermal heating.

### BACKGROUND

The creation of metal and metal oxide patterns is required in a variety of applications, including microelectronics and carbon nanotubes. Typically, the metal pattern processes are performed through a complicated series of lithography and etch steps, which are often wasteful and expensive.

In connection with such patterning processes, there are several obstacles facing the direct deposition of metallic thin films. Thermal atomic layer deposition (ALD) of metals is challenging to achieve due to the availability of metal precursors with high thermal stability and low reactivity of the co-reactant. In many developed thermal chemical vapor deposition (CVD) or ALD processes, metal films, such as ruthenium, nickel, and cobalt, can suffer from poor nucleation depending on the substrate, require high growth temperatures (>250° C.), and have low deposition rates. This islanded growth leads to rough, large-grained polycrystalline columnar films. In an application, such as a liner in backend processing where films should be smooth and nanocrystalline (or amorphous) with minimal grain boundaries, this type of growth is very problematic. Plasma-enhanced atomic layer deposition has been used to overcome the reactivity limitations of thermal based metal ALD processes by using plasma-generated ions; however, these ions can be damaging to the substrate.

One active area of research that serves as an alternative to conventional patterning strategies is area-selective atomic layer deposition (AS-ALD). AS-ALD capitalizes on specific surface chemistries to selectively deposit material on a substrate. There are two general approaches to AS-ALD which can be distinguished by area-deactivation or area-activation of the surface. In the area-deactivation approach, a surface is patterned with functional groups that are unreactive to the ALD precursors. These functional groups are used to create hydrophobic and hydrophilic regions on the surface. The ALD precursors preferentially react with the region that has no functional groups and in a self-limiting fashion, deposit only in the preferred region until the desired thickness of the pattern has been achieved. Self-assembled monolayers (SAMs) and polymers have been used to create these hydrophobic and hydrophilic regions. In the second area-activation approach, AS-ALD is accomplished by patterning a seed layer that can catalyze the reaction of the subsequent ALD process. For this approach to be effective, the nucleation on the substrate surface (i.e., regions of the substrate where the patterned seed layer is not present) must also be suppressed.

Both of these approaches have several drawbacks. For the AS-ALD by deactivation approach, although SAMs and polymers are well-suited for tailoring surface chemistries, they are thermally sensitive. At high temperatures, they become susceptible to decomposition, inter-material diffusion, and de-adsorption from the surface, which can lead to many defects. On the other hand, the AS-ALD by activation approach is typically restricted to ALD precursors that have drastic differences in reactivity on dissimilar substrates. Both area-activation and area-deactivation AS-ALD methods are unsuitable for plasma ALD processes because plasma is non-preferential and can destroy the organic self-assembled monolayers.

Furthermore, both area-activation and area-deactivation AS-ALD methods are deficient in terms of control and uniformity, cost and the ability to pattern features in the sub-5 nm scale.

### SUMMARY

In one embodiment of the present invention, a method for creating metal patterns comprises depositing a metal oxide film on a substrate in a reactor. The method further comprises feeding a reducing gas into the reactor. The method additionally comprises pulsing a heat source to heat and form metal regions on the metal oxide film within a metal's reduction window.

In another embodiment of the present invention, a method for creating metal patterns comprises depositing a metal film on a substrate in a reactor. The method further comprises feeding an oxidizing gas into the reactor. The method additionally comprises pulsing a heat source to heat and form metal oxide regions on the metal film within a metal's oxidation window.

The foregoing has outlined rather generally the features and technical advantages of one or more embodiments of the present invention in order that the detailed description of the present invention that follows may be better understood. Additional features and advantages of the present invention will be described hereinafter which may form the subject of the claims of the present invention.

### BRIEF DESCRIPTION OF THE DRAWINGS

A better understanding of the present invention can be obtained when the following detailed description is considered in conjunction with the following drawings, in which:

FIG. 1 is a flowchart of a method for patterning a metal region on a metal oxide film in accordance with an embodiment of the present invention;

FIGS. 2A-2E depict the cross-sectional views of patterning a metal region on a metal oxide film during the fabrication steps described in FIG. 1 in accordance with an embodiment of the present invention;

FIG. 3 is the cross-sectional view for uniform patterned lines in accordance with an embodiment of the present invention; and

FIG. 4 illustrates the resulting XP spectra of several locations on a sample where metal regions were patterned using the method of FIG. 1 in accordance with an embodiment of the present invention.

### DETAILED DESCRIPTION

As stated in the Background section, the area-activation and area-deactivation AS-ALD methods have several drawbacks. For the AS-ALD by deactivation approach, although SAMs and polymers are well-suited for tailoring surface chemistries, they are thermally sensitive. At high temperatures, they become susceptible to decomposition, inter-material diffusion, and de-adsorption from the surface, which can lead to many defects. On the other hand, the AS-ALD by activation approach is typically restricted to ALD precursors that have drastic differences in reactivity on dissimilar substrates. Both area-activation and area-deactivation AS-ALD methods are unsuitable for plasma ALD processes because plasma is non-preferential and can destroy the organic self-assembled monolayers. Furthermore, both area-activation and area-deactivation AS-ALD methods are deficient in terms of control and uniformity, cost and the ability to pattern features in the sub-5 nm scale.

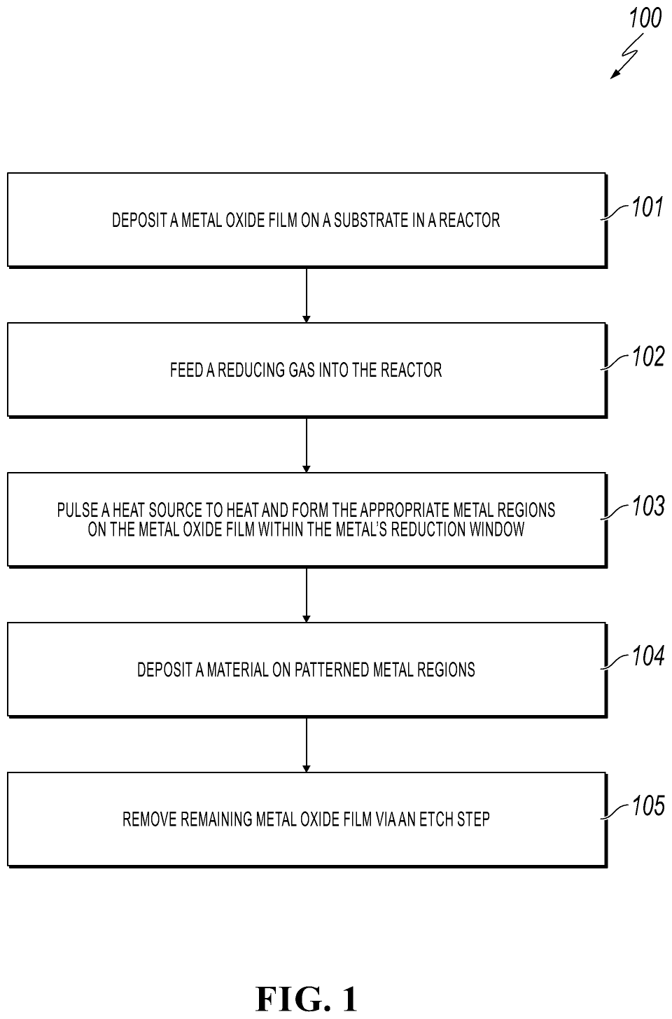

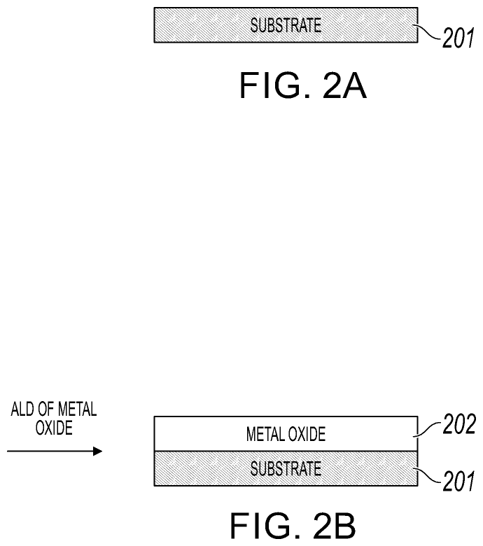

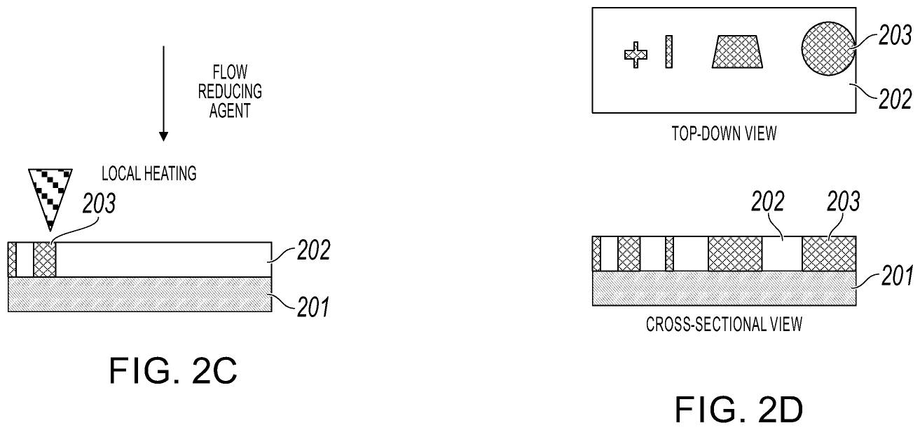

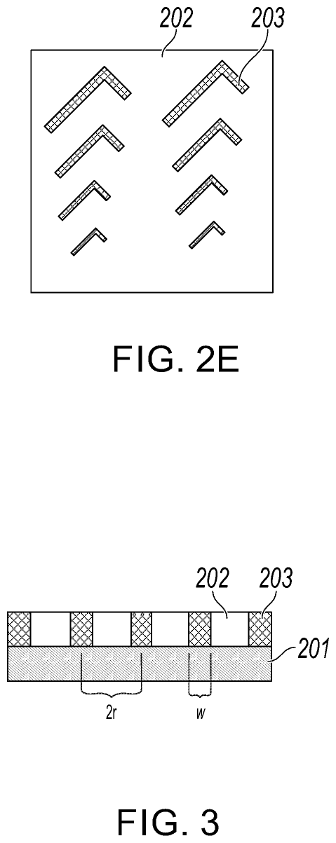

The principles of the present invention provide many benefits over the aforementioned AS-ALD patterning techniques, including greater control and uniformity, reduced cost, less waste and potential for sub-5 nm features. Such benefits are achieved, at least in part, due to reducing the number of patterning steps and not relying on SAMs/polymers or a limited selection of ALD precursors as discussed further below in connection with FIG. 1 and FIGS. 2A-2E.

FIG. 1 is a flowchart of a method for patterning a metal region on a metal oxide film in accordance with an embodiment of the present invention. FIGS. 2A-2E depict the cross-sectional views of patterning a metal region on a metal oxide film during the fabrication steps described in FIG. 1 in accordance with an embodiment of the present invention.

While FIG. 1 discusses the process in patterning a metal region on a metal oxide film, the principles of the present invention apply to patterning metal oxide regions or lines on a metal film by selective oxidation. A person of ordinary skill in the art would be capable of applying the principles of the present invention to such implementations. Further, embodiments applying the principles of the present invention to such implementations would fall within the scope of the present invention.

Referring now to FIG. 1, in conjunction with FIGS. 2A-2E, in step 101, a metal oxide film 202 (or metal film in an alternative embodiment) is deposited on a substrate 201 in a reactor as shown in FIGS. 2A and 2B. In one embodiment, metal oxide film 202 is deposited on substrate 201 using atomic layer deposition (ALD). In such an embodiment, the metal oxide depositions are carried out in a flow reactor. A carrier gas (e.g., nitrogen gas (N₂)) is fed into the flow reactor held at vacuum (e.g., 0.6-1 mbar pressure) and the metal oxide precursors are pulsed sequentially. For example, for cobalt oxide deposition, cyclopentadienyl, cobalt dicarbonyl, and ozone would be sequentially pulsed and purged in the reactor. In the alternative embodiment involving the deposition of a metal film on substrate 201, the metal film is deposited on substrate 201 using ALD.

In one embodiment, metal oxide film 202 (or metal film in the alternative embodiment) is deposited on substrate 201 using chemical vapor deposition, sputter coating or oxidation.

After the metal oxide film 202 (or metal film in the alternative embodiment) has been deposited, the desired metallic regions are formed using a reduction reaction (or oxidation reaction in the alternative embodiment) as discussed below. “Metal regions” or “metallic regions,” as used herein, refer to areas that were patterned on the metal oxide film (or metal film in the alternative embodiment), where such areas may include various geometric shapes or patterns as well as metal lines.

In step 102, a reducing gas (flow reducing agent) (e.g., 2-10% hydrogen gas (H₂) in argon (Ar)) is fed into the reactor as shown in FIG. 2C. Examples of a reducing feed gas include, but not limited to, carbon monoxide (CO) or ammonia (NH₃) (for selective oxidation of a metal film, an oxidizing gas, such as O₂, would be fed into the reactor).

In step 103, a heat source is pulsed (see local heating in FIG. 2C) to heat and form the appropriate metal regions 203 on metal oxide film 202 (or form metal oxide regions on the metal film in the alternative embodiment) within the metal's reduction window (or metal's oxidation window in the alternative embodiment) as shown in FIG. 2C. In one embodiment, the heat source consists of one or more nanoscale thermal probes. In another embodiment, the heat source consists of one or more high intensity laser beams. The resolution of such thermal reduction is constrained by the kinetics of the reduction reaction, the size of the heat source, such as the thermal probe, and the thickness of oxide film 202 (or the thickness of the metal film in the alternative embodiment).

In one embodiment, the metal's reduction window (or oxidation window in the alternative embodiment) is between 250° C. and 900° C. Such metal regions 203 that are formed may be in various geometric shapes or patterns as shown in FIG. 2D. Furthermore, such metal regions 203 may have geometric shapes in the form of metal lines as shown in FIG. 2E.

In one embodiment, for conductive materials, the size of the reduced area 203 is determined by the size of the heat source, such as the thermal probe, and the thickness of the reactant film 202.

In step 104, a material may optionally be deposited on the patterned metal regions 203 (or the patterned metal oxide regions in the alternative embodiment), such as using vapor deposition or atomic layer deposition. That is, these patterned metal regions 203 are activated for deposition.

Optionally, in step 105, the remaining metal oxide film 202 (or the remaining metal film in the alternative embodiment) is removed, such as via an etch step.

In one embodiment, the radius of the resulting reduced feature is expected to scale as r˜(α*t)^{1/2} where α is the thermal diffusivity and t is the pulse time as shown in FIG. 3. FIG. 3 is the cross-sectional view for uniform patterned lines in accordance with an embodiment of the present invention. Lateral shrinkage from the reduction will be proportional to the density of the oxide over the density of the metal so that the width w of the feature is proportional to r*ρ_{oxide}/ρₘₑₜₐₗ. By employing oxides with low thermal diffusivities and short pulse times, it is possible to achieve sub-5 nm features. Furthermore, multiple heat sources (e.g., multiple, parallelized thermal probes) (at distances (α*t)^{1/2} apart) can be used to increase the throughput of the process and to enhance temperature control over the thin film. Finally, as discussed above, if only the metal film is desired, the remaining metal oxide film can be easily removed by a subsequent etch step.

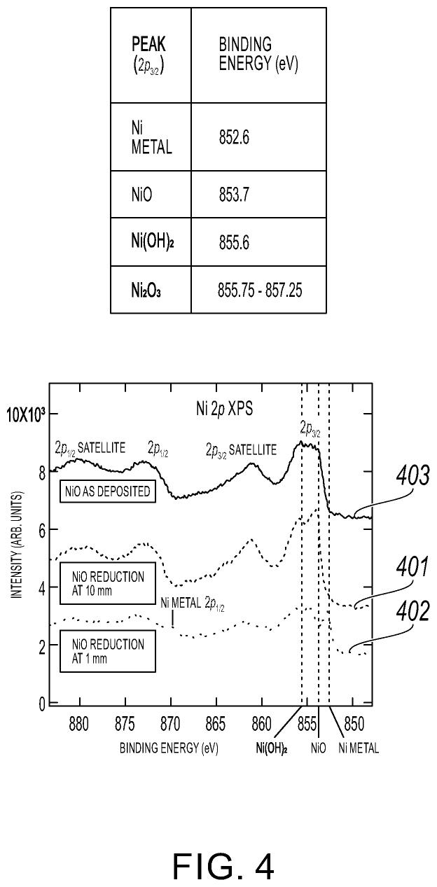

In a preliminary experiment involving method 100 as discussed above in connection with FIGS. 1 and 2A-2E, 10 nm of NiO was grown via ALD on thermally grown SiO₂ (˜300 μm) on Si. The substrate, such as substrate 201, was 20 mm×20 mm×0.5 mm. The sample was cleaved in half; one half was spot heated (soldering iron with tip temperature of ˜350° C.) while the other was kept for the control. In FIG. 4, the resulting XP spectra of several locations on the sample where metal regions 203 were patterned using the method of FIG. 1 are shown in accordance with an embodiment of the present invention.

Referring to FIG. 4, spectrum 401 is the spot heated sample ˜10 mm away from the center of heating. Spectrum 402 is the spot heated sample ˜1 mm from the center of heating. Spectrum 403 is the spot heated sample at the center of heating. The center of heating had significant film loss as evident by the very low Ni XPS signal (not shown). This is likely due to scratching of the film under the surface since the heating probe was in direct contact with the film, such as film 202. The metallic Ni 2p_{3/2} peak of the XP spectra near the center of heating is a clear indication of reduction. The absence of this peak in the film far from the center of heating indicates localized reduction around the heating spot. The Ni 2p_{1/2} peak is also visible, and the shift of its binding energy from the 2p_{3/2} peak is in agreement with literature values (Δₘₑₜₐₗ=17-17.3 eV). The spot located 1 mm away from the center of heating also shows a significant amount of Ni(OH)₂ or Ni₂O₃. NiO peaks are broad and have shoulders (see spectra 403 and spectra 401), but the peak for the reduced film is shifted suggesting the majority of the oxide is no longer Ni(II) oxide. The hydroxide may be an intermediate of the reduction reaction that did not go to completion, or the redistribution of oxygen in the film formed Ni₂O₃. These preliminary results indicate selective reduction of the NiO underneath the thermal probe.

By using localized heating for area-selective reduction, one is able to take advantage of slow reaction kinetics and diffusivity in metal oxides to create metal patterns with nanoscale resolution. Unlike other area selective methods that use self-assembled monolayers (SAMs), such an approach is not susceptible to decomposition or de-adsorption from the surface. Furthermore, such an approach does not use SAMs or metal seed layers to achieve growth in desired regions.

Furthermore, the present invention offers significant opportunities for the advancement of micro- and nano-scale electronics. Selective reduction allows for direct-write patterning of the surface and may even be used to achieve sub-5 nm features depending on the size of the thermal tip—a resolution not yet possible with current methods. This is particularly important for any applications where metal/metal oxides are required, including microelectronics, photonics, and the fabrication of both silicon and carbon nanotubes. The present invention provides greater control and uniformity of the fabricated features, reduces the number of necessary patterning steps, and generates less waste than existing processes.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A method for creating metal patterns, comprising:
depositing a metal oxide film on a substrate in a reactor;
feeding a reducing gas into said reactor; and
pulsing a heat source to heat and form metal regions on said metal oxide film within a metal's reduction window.

2. The method as recited in claim 1 further comprising:
removing a remaining metal oxide film via an etch step after said forming of said metal regions.

3. The method as recited in claim 1, wherein said metal oxide film is deposited using atomic layer deposition.

4. The method as recited in claim 3 further comprising:
feeding a carrier gas into said reactor held at vacuum; and
pulsing metal oxide precursors sequentially.

5. The method as recited in claim 4, wherein said carrier gas is nitrogen gas.

6. The method as recited in claim 1, wherein said metal oxide film is deposited using one of the following: chemical vapor deposition, sputter coating and oxidation.

7. The method as recited in claim 1, wherein said reducing gas comprises 2-10% hydrogen gas in argon.

8. The method as recited in claim 1, wherein said reducing gas comprises one of the following: carbon monoxide and ammonia.

9. The method as recited in claim 1, wherein said heat source comprises one or more nanoscale thermal probes or one or more laser beams.

10. The method as recited in claim 1, wherein said metal's reduction window is between 250° C. and 900° C.

11. The method as recited in claim 1, wherein said metal regions comprise metal lines.

12. The method as recited in claim 1 further comprising:
depositing a material on said metal regions.

13. The method as recited in claim 12, wherein said material is deposited on said metal regions using vapor deposition or atomic layer deposition.

14. A method for creating metal patterns, comprising:
depositing a metal film on a substrate in a reactor;
feeding an oxidizing gas into said reactor; and
pulsing a heat source to heat and form metal oxide regions on said metal film within a metal's oxidation window.

15. The method as recited in claim 14 further comprising:
removing a remaining metal film via an etch step after said forming of said metal oxide regions.

16. The method as recited in claim 14, wherein said metal film is deposited using atomic layer deposition.

17. The method as recited in claim 14, wherein said metal film is deposited using one of the following: chemical vapor deposition, sputter coating and oxidation.

18. The method as recited in claim 14, wherein said heat source comprises one or more nanoscale thermal probes or one or more laser beams.

19. The method as recited in claim 14, wherein said metal's oxidation window is between 250° C. and 900° C.

20. The method as recited in claim 14, wherein said metal oxide regions comprise metal lines.

21. The method as recited in claim 14 further comprising:
depositing a material on said metal oxide regions.

22. The method as recited in claim 21, wherein said material is deposited on said metal oxide regions using vapor deposition or atomic layer deposition.
